(19) United States
(12) Patent Application Publication
(10) Pub. No.: US 2005/0009275 A1
(43) Pub. Date: Jan. 13, 2005

(54) Method for fabricating semiconductor memory device

(76) Inventors: Chia-Chen Liu, Hsinchu City (TW); Hsiu-Lan Kuo, Taichung City (TW); Chih-Kuan Chen, Hsinchu City (TW)

Correspondence Address: THOMAS, KAYDEN, HOSTEMEYER & RISLEY LLP, 100 GALLERIA PARKWAY, SUITE 1750, ATLANTA, GA, 30339, US

(21) Appl. No.: 10/824,577

(22) Filed: Apr. 14, 2004

(30) Foreign Application Priority Data
Jul. 9, 2003 (TW) 092118678

(51) Int. Cl. H01L 21/8238; H01L 21/336; H01L 21/3205; H01L 21/4763

(52) U.S. Cl. 438/257; 438/593; 438/588; 438/266; 438/264

(57) ABSTRACT

A method for fabricating a one time programmable read only memory (OPTROM) device. A first conductive layer, a first semiconductor layer, an anti-fuse layer, a second semiconductor layer are sequentially formed on a substrate. The second semiconductor layer, the anti-fuse layer, the first semiconductor layer, and the first conductive layer are then patterned along the first direction into a first conductive line. The second semiconductor layer, the anti-fuse layer, and the first semiconductor layer are patterned into a memory cell. A dielectric layer is deposited over the substrate, wherein oxygen plasma sputtering is performed to clean the substrate before deposition. A second conductive line is formed over the second dielectric layer, running generally orthogonal to the first conductive line.

### BACKGROUND OF THE INVENTION

1. Field of the Invention

The present invention relates to a method for fabricating a semiconductor memory device, and more particularly, to a method of fabricating a one-time programmable read only memory (OTPROM) device.

2. Description of the Related Art

An anti-fuse memory device is a three dimensional (3D) memory device with a memory cell comprising an anti-fuse layer interposed between a PN diode. When the anti-fuse layer is intact, the cell is an open electrical circuit. When the anti-fuse layer is breached, the cell is a diode. The anode material and the cathode material are continuous orthogonally extending strips. Compared to conventional 2D memories, 3D anti-fuse memory is better suited to integration, meaning more memory devices can be built on a single wafer, thereby reducing cost.

U.S. Pat. No. 6,420,215 discloses a memory cell with low leakage. The disclosed memory cell places an anti-fuse layer between the anode and the cathode. When the anti-fuse layer is intact, the cell is electrically an open circuit. When the anti-fuse layer is breached, the anode material and cathode material converge in a small-diameter filament, and a diode is formed. The small filament gives the diode a very small area and perimeter. Thus the diode's leakage is relatively small.

U.S. Pat. No. 6,525,953 discloses an exemplary vertically-stacked, field-programmable, nonvolatile memory comprising multiple layers of first and second crossing conductors. Pillars are self-aligned at the intersection of adjacent first and second crossing conductors, and each pillar comprises at least an anti-fuse layer. The pillars form memory cells with the adjacent conductors, and each memory cell includes first and second diode components separated by the anti-fuse layer. The diode components form a diode only after the anti-fuse layer is breached.

FIG. 1 is a schematic layout of a conventional anti-fuse OPTROM device comprising a word line (WL), a bit line (BL), and a memory cell electrically connecting the word line to the bit line. FIGS. 2 to 3 are cross sections illustrating the fabrication procedure.

Referring to FIG. 2, a semiconductor substrate 10, such as monocrystalline silicon, is provided. A layer of p⁺-doped polysilicon 20 is formed on the substrate 10. A titanium layer 30 is deposited on the p⁺-doped polysilicon layer 20. Titanium nitride is formed on the titanium layer to serve as adhesion layer. A rapid thermal process (RTP) is performed reacting p⁺-doped polysilicon layer and titanium layer into a titanium silicide (TiSi₂) layer 30. The titanium silicide (TiSi₂) layer 30 possesses characteristics of low resistivity and excellent thermal stability. A layer of titanium nitride (not shown) is formed over the titanium silicide layer 30. Next, a p⁺-doped polysilicon layer 40 is formed over the titanium nitride layer.

A rapid thermal oxidation (RTO) process is subsequently performed to form an anti-fuse layer 50, such as silicon oxide, on the P⁺-polysilicon layer 40. An n-doped polysilicon layer 60 is formed over the anti-fuse layer 50.

FIG. 3 is cross section illustrating the procedure of defining word lines and memory cells. The n-doped polysilicon layer 60, the anti-fuse layer 50, the p⁺-doped polysilicon layer 40, the titanium silicide layer 30 and the p⁺-doped polysilicon layer 20 are sequentially lithographically etched generally along the first direction to form a word line. The n-doped polysilicon layer 60, the anti-fuse layer 50, the p⁺-doped polysilicon layer 40 are then lithographically etched to form a memory cell stack.

In accordance with the above mentioned processes, however, silicon residue 70 will remain on the surface of the titanium silicide layer 30 during lithographical etching the p⁺-doped polysilicon layer 40 causing short between memory cells and lowering production yield.

### SUMMARY OF THE INVENTION

Accordingly, an object of the present invention is to provide a method for fabricating an OTPROM device overcoming the shortcomings associated with the related art.

Another object of the present invention is to provide an oxygen pre-sputtering process prior to dielectric deposition for removing the silicon residue.

To obtain the above objects, the present invention provides a method for fabricating a semiconductor memory device, comprising providing a substrate, sequentially forming a first conductive layer, a first type doped semiconductor layer, a first dielectric layer, a second type doped semiconductor layer on the substrate, patterning the second type doped semiconductor layer, the first dielectric layer, the first type doped semiconductor layer, and the conductive layer along the first direction, thereby turning the conductive layer into a first conductive line, patterning the second type doped semiconductor layer, the first dielectric layer, and the first type doped semiconductor layer into a memory cell, depositing a second dielectric layer overlying the substrate, wherein oxygen plasma sputtering is employed to clean the substrate before deposition, planarizing the second dielectric layer to expose the memory cell, and forming a second conductive line overlying the second dielectric layer, running generally orthogonal to the first conductive line.

To obtain the above objects, the present invention provides a method for fabricating a one time programmable read only memory (OTPROM) device, comprising providing a substrate, sequentially forming a stack of p⁺-doped silicon/TiSi₂/TiN/p⁺-doped silicon/first dielectric/n-type doped silicon layers on the substrate, patterning the stack of p⁺-doped silicon/TiSi₂/TiN/p⁺-doped silicon/first dielectric/n-type doped silicon layers along the first direction, thereby turning the stack of p⁺-doped silicon/TiSi₂/TiN layers into a word line, patterning the stack of p⁺-doped silicon/first dielectric/n-type doped silicon layers into a memory cell, depositing a second dielectric layer overlying the substrate, wherein oxygen plasma sputtering is employed to clean the substrate before deposition, planarizing the second dielectric layer to expose the memory cell, and forming a stack of n⁺-type doped silicon/TiN/TiSi₂/n⁺-type doped silicon/n-type doped silicon layers over the second dielectric layer and patterning the same into a bit line, running generally perpendicular to the word line.

To obtain the above objects, the present invention provides a semiconductor memory device, comprising a first conductive line disposed on a semiconductor substrate, the surface of the first conductive line being substantially silicon residue free, a second conductive line running generally perpendicular to the first conductive line, a memory cell between the first line and the second line, and a dielectric layer, surrounding the memory cell, wherein the surface of the first conductive line being oxygen plasma sputtered preventing silicon residue.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinafter and the accompanying drawings which are given by way of illustration only, and thus are not limitative of the present invention, and wherein:

FIG. 1 is a schematic layout of a conventional anti-fuse OPTROM device;

FIGS. 2 to 3 are cross sections illustrating the fabrication procedure; and

FIGS. 4 to 8 are cross sections illustrating the fabrication procedures of an embodiment according to the embodiment of the present invention.

### DETAILED DESCRIPTION OF THE INVENTION

The present invention will hereinafter be described with reference to the accompanying drawings.

Compared with the related art, the key feature of the present invention is performing oxygen pre-sputtering on the surface of the titanium silicide layer to remove silicon residue, thereby improving production yield.

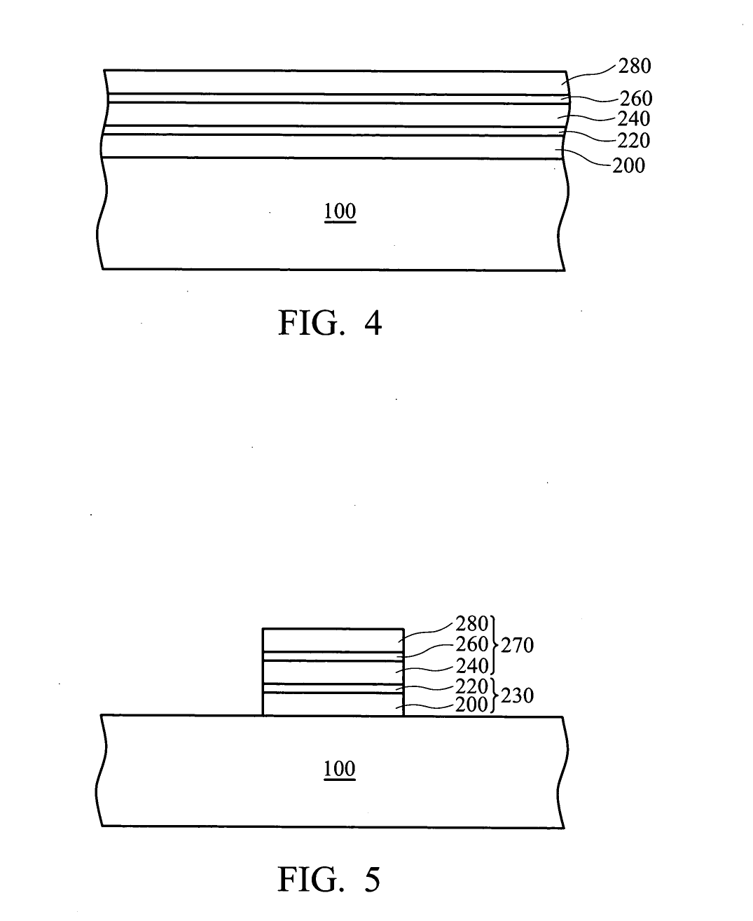

FIGS. 4 to 8 are cross sections illustrating the fabrication procedures of an embodiment according to the present invention.

Referring to FIG. 4, a semiconductor substrate 100, such as monocrystalline silicon, is provided. A conductive layer comprising a polysilicon layer 200 and a composite layer 220 of TiN/TiSi₂ is deposited over the substrate 100. The polysilicon layer 200 is heavily doped polysilicon, such as p⁺-doped polysilicon, using chemical vapor deposition (CVD) to achieve a thickness between about 1500 Å to 2500 Å, more preferably 2000 Å. Dopant, such as boron (B) or boron fluoride (BF₂), is added to the polysilicon layer 200 with a dosage of exceeding 10¹⁹ atoms/cm³.

Next, a metal layer 220, such as titanium, is deposited over the p⁺-doped polysilicon layer 200 to achieve a thickness between about 200 Å to 800 Å, more preferably 500 Å. A titanium nitride with a thickness between about 100 Å is formed over the titanium layer 200 to serve as adhesion layer. After rapid thermal processing (RTP), the p⁺-doped polysilicon layer 200 reacts the titanium layer to a titanium silicide (TiSi₂) layer 220. The titanium silicide (TiSi₂) layer 220 possesses characteristics of low resistance and excellent thermal stability. The rapid thermal processing (RTP) is performed at a temperature of about 400 to 1200° C., more preferably 675° C. with inert gases. The resistivity of the titanium silicide (TiSi₂) layer 220 is approximately 10 to 200 μΩ-cm.

A heavily p⁺-doped polysilicon layer 240 is formed over the TiN/TiSi₂ layer 220 as top polysilicon layer 240. The p⁺-doped polysilicon layer 240 is heavily doped polysilicon, such as p⁺-doped polysilicon, using chemical vapor deposition (CVD) to achieve a thickness between about 400 Å to 600 Å, more preferably 500 Å. Dopant, such as boron (B) or boron fluoride (BF₂), is added to the polysilicon layer 240 with a dosage of exceeding 10¹⁹ atoms/cm³.

A rapid thermal oxidation (RTP) process is performed at a temperature of about 400° C. to 650° C. for 30 to 60 seconds using N₂ and O₂ gases. The rapid thermal oxidation (RTO) process is subsequently performed to form the p⁺-doped polysilicon layer 240. The surface of the p⁺-doped polysilicon layer 240 is oxidized to form a thin silicon oxide layer as an anti-fuse layer 260 with a thickness of about 5 Å to 20 Å, more preferably 14.5 Å.

An n-doped polysilicon layer 280 is formed over the anti-fuse layer 260. The n-doped polysilicon layer 280 is doped polysilicon, such as n-doped polysilicon, using chemical vapor deposition (CVD) to achieve a thickness of between about 3000 Å to 4000 Å, more preferably 3500 Å. Dopant, such as phosphorus (P) or arsenic (As), is added to the polysilicon layer 280 with a dosage of about 10¹⁵ to 10¹⁷ atoms/cm³.

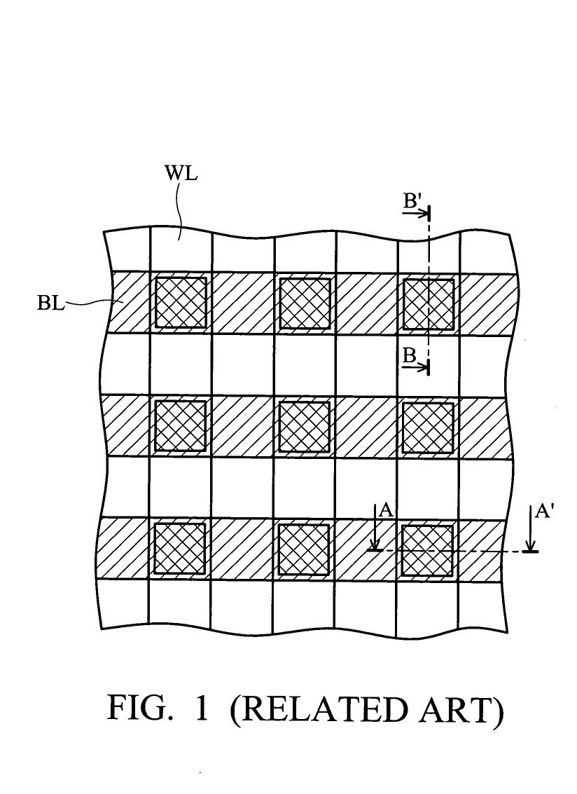

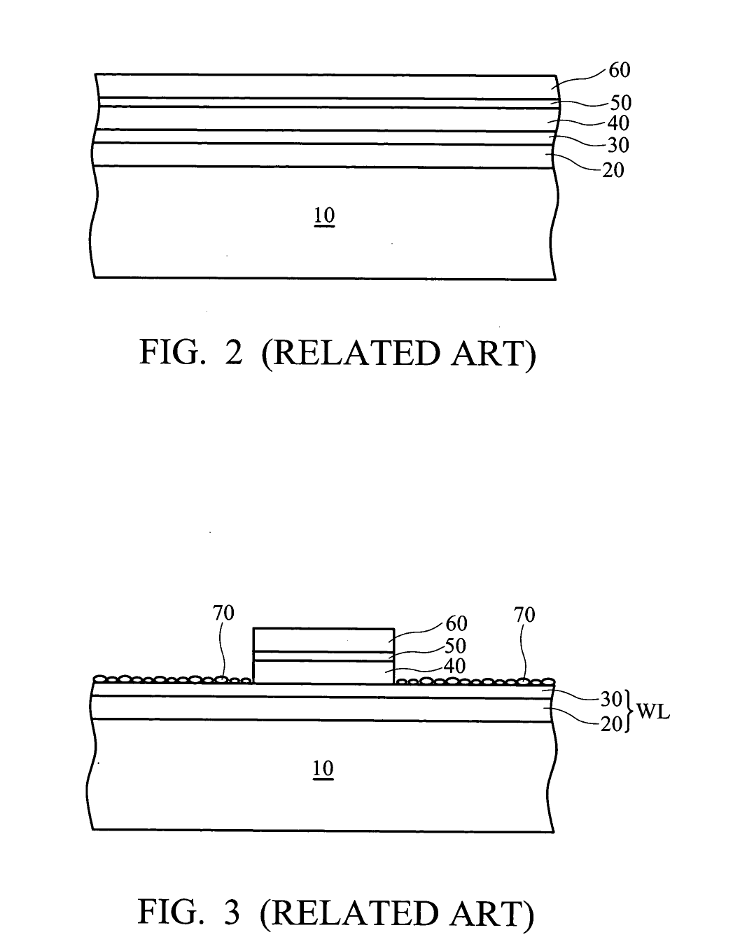

FIG. 5 is cross section of FIG. 1 along the line A-A′illustrating the procedure of defining word lines (WL). The n-doped polysilicon layer 280, the anti-fuse layer 260, the top p⁺-doped polysilicon layer 240, the titanium silicide layer 220 and the bottom p⁺-doped polysilicon layer 200 are sequentially lithographically etched generally along the first direction (east-to-west) to form long straight strips serving as word lines (WL).

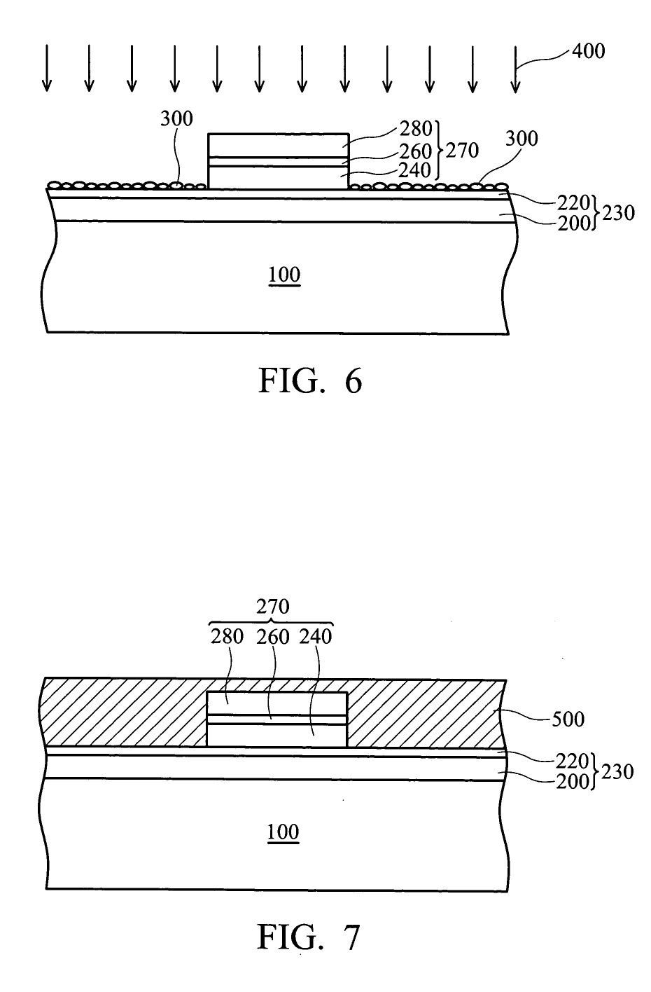

FIG. 6 is cross section of FIG. 1 along the line B-B′ illustrating the procedure of defining a memory pillar. The n-doped polysilicon layer 280, the anti-fuse layer 260, the p⁺-doped polysilicon layer 240 are then lithographically etched to form a memory cell 270. During the above mentioned etching processes, particulate silicon residue 300 will remain on the surface of the titanium silicide layer 220 causing a BL bridge problem. To remove the silicon residue 300, pre-sputtering 400 is performed before dielectric deposition using O₂ with a flow rate of 300-400 sccm and Ar gas with a flow rate of 200-250 sccm, at a temperature of about 225 to 275° C., and a power of about 1000-1500 W. More preferably, the pre-sputtering 400 is performed using O₂ with a flow rate of 340 sccm and Ar gas with a flow rate of 240 sccm, at a temperature of about 250° C., and a power of about 1300 W.

Oxidization may alternatively be performed during the above pre-sputtering 400 to transform the silicon residue 300 into silicon oxide which is an insulator.

Referring to FIG. 7, the spaces between each memory cell 270 and each first conductive line 230 are then filled with dielectric 500 such as silicon dioxide, using high density plasma chemical vapor deposition (HDPCVD). During the HDPCVD process, the density of the active ions exceeds that of the conventional CVD process. As a result, the HDPCVD process is cable of accomplishing both deposition and etching simultaneously such that substantially void-free filling is achieved. The dielectric 500 is then planarized by chemical mechanical polishing (CMP) exposing the surface of the memory cell 270.

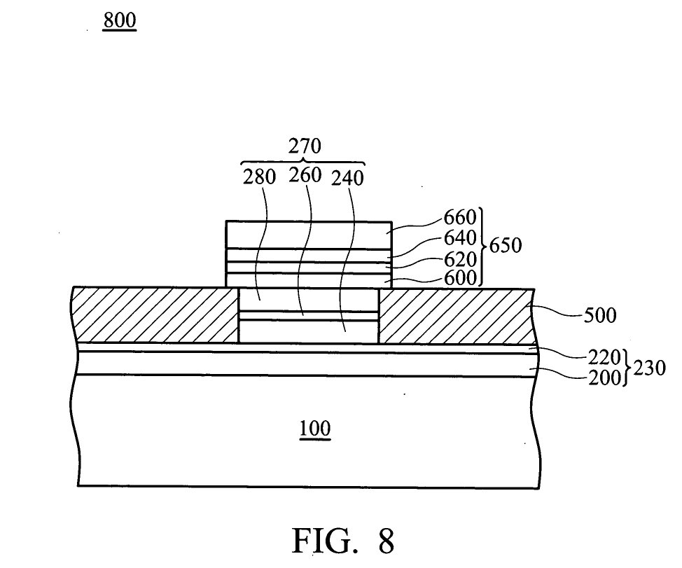

Referring FIG. 8, a second conductive line 650 is formed on the second dielectric 500, substantially orthogonal to the first conductive line 230. The second conductive line 650 comprises a stack of an n⁺-doped polysilicon layer 600, a metal silicide layer 620, an n⁺-doped polysilicon layer 640 and an n-doped polysilicon layer 660.

The N⁺-doped polysilicon layer 600 is heavily doped polysilicon, such as n⁺-doped polysilicon, using chemical vapor deposition (CVD) to achieve a thickness between about 1500 Å to 2500 Å, more preferably 2000 Å. Dopant, such as phosphor (P) or arsenic (As), is added to the polysilicon layer 600 with a dosage exceeding 10¹⁹ atoms/cm³.

A metal layer 620, such as titanium, with a thickness of between about 200 Å to 800 Å, more preferably 500 Å is deposited over the n⁺-doped polysilicon layer 600. A titanium nitride layer with a thickness of about 100 Å (not shown) is formed over the titanium layer 620 to serve as an adhesion layer to a thickness between about. After rapid thermal processing (RTP), the n⁺-doped polysilicon layer 600 reacts the titanium layer 620 to a titanium silicide (TiSi₂) layer 620. The titanium silicide (TiSi₂) layer 620 possesses characteristics of low resistance and excellent thermal stability. The rapid thermal processing (RTP) is performed at a temperature of about 400 to 1200° C., more preferably 675° C. with inert gases. The resistivity of the titanium silicide (TiSi₂) layer 620 is approximately 10-200 μΩ-cm.

A second type doped polysilicon layer 640 is heavily doped polysilicon, such as n⁺-doped polysilicon, using chemical vapor deposition (CVD) to achieve a thickness between about 400 Å to 600 Å, more preferably 500 Å. Dopant, such as phosphor (P) or arsenic (As), is added to the polysilicon layer 640 with a dosage exceeding 10¹⁹ atoms/cm³.

The n-doped polysilicon layer 660 is deposited on the n⁺-doped polysilicon layer 640, using chemical vapor deposition (CVD) to achieve a thickness between about 3000 Å to 4000 Å, more preferably 3500 Å. Dopant, such as phosphor (P) or arsenic (As), is added to the polysilicon layer 660 with a dosage of between about 10¹⁵ and 10¹⁷ atoms/cm³.

The n-doped polysilicon layer 660, n⁺-doped polysilicon layer 640, metal silicide layer 620, and an n⁺-doped polysilicon layer 660 are sequentially lithographically etched creating a second conductive line 650 running generally perpendicular to the first conductive line as a bit line (BL).

Again referring to FIG. 8, the completed anti-fuse semiconductor memory device 800 is described as follows. The semiconductor memory device 800 comprises a first conductive line 120 overlying a semiconductor substrate 100 running through a first direction (e.g., east-to-west). The surface of the first conductive line 120 is substantially silicon residue free. A memory cell 140 is disposed over the first conductive line 120. A second conductive line 160 electrically connecting the memory cell 140 is formed, running orthogonal (e.g., north-to-south) to the first conductive line 120. The spaces between each conductive line 230 and each memory cell 270 are filled with dielectric layer 500.

The invention been thus described, it will be obvious that the same may be varied in many ways. Such variations are not to be regarded as a departure from the spirit and scope of the invention, and all such modification as would be obvious to one skilled in the art are intended to be included within the scope of the following claims.

1. A method of fabricating a semiconductor memory device comprising:
providing a substrate;
sequentially forming a first conductive layer, a first type doped semiconductor layer, a first dielectric layer, a second type doped semiconductor layer on the substrate;
patterning the second type doped semiconductor layer, the first dielectric layer, the first type doped semiconductor layer, and the conductive layer along the first direction, thereby turning the conductive layer into a first conductive line;
patterning the second type doped semiconductor layer, the first dielectric layer, and the first type doped semiconductor layer into a memory cell;
depositing a second dielectric layer overlying the substrate, wherein oxygen plasma sputtering is employed to clean the substrate before deposition;
planarizing the second dielectric layer to expose the memory cell; and
forming a second conductive line overlying the second dielectric layer, running generally orthogonal to the first conductive line.

2. The method according to claim 1, wherein the first type doped semiconductor layer is a p⁺-type doped silicon layer.

3. The method according to claim 1, wherein the first conductive layer comprises a stack of TiN/TiSi₂/p⁺-type doped silicon layers.

4. The method according to claim 1, wherein the first conductive line is a word line.

5. The method according to claim 1, wherein formation of the first dielectric layer comprises rapid thermal oxidation of silicon.

6. The method according to claim 1, wherein the second type doped silicon layer is n-type doped silicon layer.

7. The method according to claim 1, wherein the memory cell comprises a stack of p⁺-type doped silicon/first dielectric/n-type doped silicon layers.

8. The method according to claim 1, wherein the step of oxygen plasma sputtering is performed using oxygen gas with a flow rate between about 300 and 400 sccm.

9. The method according to claim 8, wherein the step of oxygen plasma sputtering is performed using argon gas at with a flow rate between about 200 and 250 sccm.

10. The method according to claim 8, wherein the step of oxygen plasma sputtering is performed at a temperature within a range of about 225 to 275° C.

11. The method according to claim 7, wherein the step of oxygen plasma pre-sputtering is performed at a power within a range of about 1000 to 1500 W.

12. The method according to claim 1, wherein the second conductive layer comprises a stack of n⁺-type doped silicon/TiN/TiSi₂/n⁺-type doped silicon/n-type doped silicon layers.

13. The method according to claim 1, wherein the second conductive line is a bit line.

14. A method of fabricating one time programmable read only memory (OPTROM) device, comprising:
providing a substrate;
sequentially forming a stack of p⁺-doped silicon layer/titanium silicide/titanium nitride/p⁺-doped silicon layer/first dielectric/n-type doped silicon layers on the substrate;
patterning the stack of p⁺-doped silicon layer/titanium silicide/titanium nitride/p⁺-doped silicon layer/first dielectric/n-type doped silicon layers along the first direction, thereby turning the stack of p⁺-doped silicon layer/titanium silicide/titanium nitride layers into a word line;
patterning the stack of p⁺-doped silicon layer/first dielectric/n-type doped silicon layers into a memory cell;
depositing a second dielectric layer overlying the substrate, wherein oxygen plasma sputtering is employed to clean the substrate before deposition;
planarizing the second dielectric layer to expose the memory cell; and
forming a stack of n⁺-type doped silicon/ titanium nitride/ titanium silicide /n³⁰ -type doped silicon/n-type doped silicon layers over the second dielectric layer and patterning the same into a bit line, running generally perpendicular to the word line.

15. The method according to claim 14, wherein formation of the first dielectric layer comprises rapid thermal oxidation of silicon oxide.

16. The method according to claim 14, wherein the step of oxygen plasma sputtering is performed using oxygen gas with a flow rate between about 300 and 400 sccm.

17. The method according to claim 14, wherein the step of oxygen plasma sputtering is performed using argon gas with a flow rate between about 200 and 250 sccm.

18. The method according to claim 14, wherein the step of oxygen plasma sputtering is performed at a temperature within a range of about 225 to 275° C.

19. The method according to claim 14, wherein the step of oxygen plasma pre-sputtering is performed at a power within a range of about 1000 to 1500 W.

20. A semiconductor memory device comprising:
a first conductive line disposed on a semiconductor substrate, the surface of the first conductive line being substantially silicon residue free;
a second conductive line running generally perpendicular to the first conductive line;
a memory cell between the first line and the second line; and
a dielectric layer, surrounding the memory cell;
wherein the surface of the first conductive line is oxygen plasma sputtered for preventing accumulation of silicon residue.

21. The semiconductor memory device according to claim 20, wherein the first conductive line is word line and the second conductive line is bit line.

22. The semiconductor memory device according to claim 20, wherein the first conductive line comprises a stack of TiN/TiSi₂/p⁺-type doped silicon layers.

23. The semiconductor memory device according to claim 20, wherein the memory cell comprises a stack of p⁺-doped silicon layer/first dielectric/n-type doped silicon layers.

24. The semiconductor memory device according to claim 20, wherein formation of the first dielectric layer comprises rapid thermal oxidation of silicon oxide.

25. The semiconductor memory device according to claim 20, wherein the second conductive layer comprises a stack of n⁺-type doped silicon/TiN/TiSi₂/n⁺-type doped silicon/n-type doped silicon layers.
